(19) United States
(12) Patent Application Publication
(10) Pub. No.: US 2024/0353960 A1
(43) Pub. Date: Oct. 24, 2024

(54) TOUCH-SENSITIVE CONTROLLER AND INTERFACE, AND METHODS

(71) Applicant: International Controls and Measurements Corporation, North Syracuse, NY (US)

(72) Inventors: Eric Christopher WOOD, East Syracuse, NY (US); Hollis GMYR, Baldwinsville, NY (US)

(73) Assignee: International Controls and Measurements Corporation, North Syracuse, NY (US)

(21) Appl. No.: 18/643,299

(22) Filed: Apr. 23, 2024

Related U.S. Application Data
(60) Provisional application No. 63/498,009, filed on Apr. 24, 2023.

(51) Int. Cl. G06F 3/044; G06F 3/041; H05K 5/00

(52) U.S. Cl. CPC G06F 3/044; G06F 3/0416; H05K 5/0018

(57) ABSTRACT

A controller, comprising first and second housing pieces, a capacitive touch sensor, a circuit board, and a label, the first housing piece ultrasonically welded to the second housing piece, the capacitive touch sensor attached to the first housing piece, the label in-mold decorated on the first housing piece. Also, a controller, comprising a panel comprising substantially rigid dielectric material having a first housing piece and a second housing piece, a principal circuit board., a capacitive touch sensing interface, a microprocessor, a multi-conductor cable, and a label, the first housing piece ultrasonically welded to the second housing piece, the label in-mold decorated on the first housing piece. Also, a method of making a controller and an ornamental design for a controller.

### CROSS-REFERENCE TO RELATED APPLICATIONS

This application claims the benefit under 35 U.S.C. 119 section (e) of U.S. Provisional Patent Application No. 63/498,009, filed Apr. 24, 2023, the entirety of which is incorporated herein by reference.

### BACKGROUND OF THE INVENTION

There are a variety of controllers for various devices and systems, and there is an ongoing need for controllers that are easier to use, more accurate, easier to make, provide different or better functionalities, and/or any other combination of features.

In some aspects, it is an object of the present invention to provide a durable and reliable touch screen controller (e.g., a control panel) that avoids the drawbacks of the prior art.

In some aspects, it is an object of the present invention to provide a touch screen controller (e.g., a control panel) that is simple to use and operate, and which can be made highly resistant to caustic elements and contaminants in the environment in which it is used.

In some aspects, it is an object of the present invention to provide a touch screen controller that is of simple design, inexpensive to manufacture and install.

U.S. Pat. No. 9,734,771 is hereby incorporated by reference in its entirety, as if set forth fully herein.

### SUMMARY OF THE INVENTION

This section (i.e., “Summary of the Invention”) presents a simplified summary of the present invention in order to provide a basic understanding of some aspects of the invention. Included in this section are some concepts of the invention as a prelude to more detailed descriptions of aspects of the present invention, and representative embodiments in accordance with aspects of the present invention.

In some aspects, the present invention relates to controllers (e.g., control panels) for controlling apparatus or appliances of various types, including control panels that are touch sensitive. In some aspects, the present invention is directed to touch-sensitive control panels that are made substantially rigid and avoid mechanical switch elements.

In some aspects, the present invention is directed to a control panel that is provided with a generally flat rigid or semi-rigid front panel or plate, and which has capacitive touch sensor pads behind the front panel, and which is sealed (e.g., hermetically sealed) for use in harsh environments.

Touch sensors are an attractive choice in many environments because they require no moving parts, and the surface presented to the user can be a plain, smooth surface which can be sealed to prevent moisture, dust, and other contaminates from entering and compromising the control panel, and which can be easily cleaned. Also, in some embodiments, the touch sensors are made transparent or translucent, at least in part, which permits them to be back-lit, e.g., with LEDs, to assist or guide the user or operator when employing the touch panel to set or operate the associated equipment.

One example of an application for a control panel where a capacitive touch screen can provide an advantage is in a controller for swimming pool and/or spa equipment such as a water heater or heater and chiller, where the controls are or may be exposed to moisture and caustic chemicals. These control panels are typically mounted on the shell or housing of a pool water heater, a spa water heater, or a pool and spa water heater, which may also include one or more pumps and filtration equipment. This equipment may be in the form of a heat pump which can be configured for cooling as well as heating the water for the pool and/or spa. At a minimum, this would require the controls to switch between modes for heating and cooling, and to allow the operator to adjust the heating and possibly cooling set points for the pool and/or the hot-tub.

In some aspects, the present invention provides a control panel that includes a display, e.g., a display that is visible through an opening in the panel (or through a transparent window region of the panel), that can show the water temperature, the programmed temperature setpoint(s), indications of the mode in which the pool or spa is operating, indications of which features or the pool or spa are active, and/or indications of which features can be selected and changed.

Capacitive touch-screen controllers in accordance with the present invention can be employed in any of a wide variety of other applications, e.g., (as a specific representative example), a touch-screen controller in accordance with the present invention can be use for adjusting the height of a work space desk or work surface in an emergency work station.

In accordance with a first aspect of the present invention, there is provided a controller, comprising:
a first housing piece;
a second housing piece;
a capacitive touch sensor
a circuit board; and
a label,
the first housing piece ultrasonically welded to the second housing piece,
the capacitive touch sensor attached to the first housing piece,
the label in-mold decorated on the first housing piece.

By in-mold decorating the first housing piece, it is possible to facilitate ultrasonically welding the first housing piece to the second housing piece while having the ability to print (decorate) the entire face of the device

In some embodiments in accordance with the first aspect of the present invention, the controller further comprises a display which is visible through an opening in the first housing piece, or through a transparent region in the first housing piece.

In some embodiments in accordance with the first aspect of the present invention, the controller is configured to control at least one aspect of operation of pool equipment and/or spa equipment by a user touching the capacitive touch sensor.

In some embodiments in accordance with the first aspect of the present invention, the aspect of operation of pool equipment and/or spa equipment is water temperature.

In accordance with a second aspect of the present invention, there is provided a controller, comprising:
a panel comprising substantially rigid dielectric material having a first housing piece and a second housing piece;
a principal circuit board having a front side and a reverse side, the reverse side being a component side on which circuit elements are mounted, and the front side being flat and without components thereon, the principal circuit board including at least one display module mounted on the reverse side of the principal circuit board, and the at least one display module having a visible display on a front face thereof;
a capacitive touch sensing interface;
a microprocessor mounted on the reverse side of said principal circuit board and having a plurality of input electrodes and output electrodes; an array of conductors on said principal circuit board connecting at least some of the input electrodes and output electrodes of the microprocessor to said at least one display module, and to said capacitive touch sensing interface;
a multi-conductor cable connected with said array of conductors and extending from said principal circuit board and adapted to connect to a control component associated with said interface; and
a label,
the first housing piece ultrasonically welded to the second housing piece,
the label in-mold decorated on the first housing piece.

In some embodiments in accordance with the second aspect of the present invention,
the controller is configured to control at least one aspect of operation of pool equipment and/or spa equipment by a user touching the capacitive touch sensor.

In some embodiments in accordance with the second aspect of the present invention, the aspect of operation of pool equipment and/or spa equipment is water temperature.

In accordance with a third aspect of the present invention, there is provided a method of making a controller, comprising:
in-mold decorating a label on a first housing piece;
ultrasonically welding the first housing piece to a second housing piece, thereby forming a housing with at least one internal space,
a capacitive touch sensor in the at least one internal space and configured to be activated by touching the first housing piece.

In some embodiments in accordance with the second aspect of the present invention, the controller further comprises a display in the at least one internal space.

In some embodiments in accordance with the second aspect of the present invention, the controller further comprises a circuit board in the at least one internal space.

In some embodiments in accordance with the second aspect of the present invention, the controller is configured to control at least one aspect of operation of pool equipment and/or spa equipment by a user touching the capacitive touch sensor.

In some embodiments in accordance with the second aspect of the present invention, the aspect of operation of pool equipment and/or spa equipment is water temperature.

In a variation or alternative embodiment, the positions of the capacitive touch pads can be illuminated when active, as a guide for the user or operator. In such case, there can be LEDs positioned on the back or rear side of said circuit board at locations in registry with the respective capacitive electrode pads, and with the board and said capacitive electrode pads being at least partly translucent or transparent at the locations of these LEDs. In such embodiments, a microprocessor is operative to illuminate the respective LEDs when the associated touch-screen control panel interface is in an active condition and to hold the LEDs off when the touch-screen control panel interface is in an inactive condition.

In some embodiments, an array of metallized capacitive electrode pads are arranged in a row on the circuit board. A microprocessor is suitably programmed to switch the touch screen control panel interface into an inactive condition after a predetermined time of inactivity, and to switch the touch screen control panel interface into an active condition when the microprocessor detects that the capacitance on the electrode pads has changed, in row order, to indicate a swipe past the row of said capacitive electrode pads. This feature will avoid having the control panel accidentally change the mode of operation or the settings of associated equipment, such as from having a bird or squirrel land on the control panel at the location of one or more of the capacitive electrode pads, or from falling water such as rainfall or hose spray landing on the control panel.

In some embodiments, an array of metallized capacitive electrode pads are arranged in any convenient predetermined pattern on the circuit board and a microprocessor is suitably programmed to switch the touch screen control panel interface into an inactive condition after a predetermined time of inactivity, and to switch the touch screen control panel interface into an active condition when the microprocessor detects that the capacitance on the electrode pads has changed in a predetermined order of the pattern of the capacitive electrode pads.

The capacitive electrode pads can be metallized, e.g., by using a silver screen-printed ink, a nano-silver ink jet, a nano-copper screen-printed ink, or a nano-copper ink jet, for example, and printed on the forward surface of the printed circuit board, or on the back surface of the front plate, or on an intermediate membrane.

In some embodiments, the construction can employ stacked printed circuit boards, in which a first printed circuit board is adhered to the front plate or panel (first housing piece), and then is encapsulated by filling it with a suitable potting resin. Where the application employs an LCD module as the display device, a cap or cover is adhered onto the module prior to potting as a protective cap so as to keep the resin out. A second printed circuit board is stacked within the potting frame and is interconnected with the first printed circuit board using a board-to-board connector. Once the second board is in place resin is flowed in to encapsulate the second board as well. Channels on the side walls of the potting barrier may be used for flowing in the potting resin. This construction is not limited only to two stacked boards; rather, any number of boards may be stacked and (optionally) potted, in parallel or perpendicular orientation.

In some embodiments, the controller comprises a wireless transmitter and/or a wireless antenna (e.g., a wireless transceiver) configured to enable one-way or two-way communication with one or more other devices (e.g., two-way from the controller to a transceiver on a remote device, or one-way from the controller to an antenna or transceiver on a remote device).

The above and other features and advantages of the touch screen control panel of the present invention can be appreciated from the ensuing detailed description of selected preferred embodiments, which is to be read in connection with the accompanying drawing figures.

The invention may be more fully understood with reference to the accompanying drawings and the following detailed description of the invention.

### BRIEF DESCRIPTION OF DRAWINGS

FIG. 1 schematically depicts a controller in the form of a hermetically sealed capacitive touch screen control panel 10 according to a first embodiment.

FIG. 2 schematically depicts an exploded view of the controller 10 taken from a first perspective.

FIG. 3 schematically depicts an exploded view of the controller 10 taken from a second perspective (opposite from the first perspective).

FIGS. 4 and 5 schematically depict another example of a suitable printed circuit board 29.

FIGS. 6 and 7 schematically depict partial back and front views of an alternative arrangement of the printed circuit board 29′ for a blank or “dead-face” control panel.

FIG. 8 schematically illustrates an alternative controller 40 configured for a different style cabinet or housing and for different equipment.

FIG. 9 is an ornamental design of a front face of a controller.

FIG. 10 is a front view of another controller.

FIG. 11 is a rear view of the controller depicted in FIG. 10;

FIG. 12 is a top view of the controller depicted in FIG. 10;

FIG. 13 is a bottom view of the controller depicted in FIG. 10;

FIG. 14 is a left side view of the controller depicted in FIG. 10;

FIG. 15 is a right side view of the controller depicted in FIG. 10;

FIG. 16 is a rear view of a controller in accordance with the present invention, with an

external connector poised to make an ingress-protected connection to a connector (including a plurality of connector pins) in the controller; and

FIG. 17 is a rear view of the controller depicted in FIG. 16, with the external connector ingress-protected connected to the connector in the controller.

### DETAILED DESCRIPTION OF THE INVENTION

The expression “invention” is used herein to refer to any portion (or portions) of the inventive subject matter disclosed herein. As described herein, the present invention includes many aspects.

The expression “comprises” or “comprising,” as used herein, is used in accordance with its well-known usage, and means that the item that “comprises” the recited elements (or that is “comprising” the recited elements) includes at least the recited elements, and can optionally include any additional elements. For example, an item that “comprises a first housing piece; a second housing piece; a capacitive touch sensor; a circuit board; and a label” includes at least one capacitive touch sensor, at least one circuit board, . . . , i.e., it can include a single capacitive touch sensor or a plurality of capacitive touch sensors (and likewise can include a single circuit board or a plurality of boards, etc. An item that comprises at least first and second recited elements can include the two recited elements or can include three or more of the recited elements (e.g., a housing that comprises a first housing piece and a second housing piece can optionally also comprise a third housing piece, or third and fourth housing pieces, etc).

The expression “embodiment,” as used herein, means an embodiment in accordance with the present invention, i.e., an embodiment that is encompassed within the present inventive subject matter.

The expression “defines an internal space,” as used herein, means that the item (e.g., a housing) that “defines” the internal space substantially completely surrounds the space by itself or in combination with one or more other elements (e.g., a display).

The expression “substantially completely surrounds the space,” as used herein, means that the item that substantially completely surrounds the space occupies at least 90 percent of the surface area of an imaginary shape that completely surrounds the space.

Unless otherwise defined, all terms (including technical and scientific terms) used herein have the same meaning as commonly understood by one of ordinary skill in the art to which this invention belongs. Terms and expressions, such as those defined in commonly used dictionaries, should each be interpreted as having a meaning that is consistent with their meaning in the context of the relevant art and the present disclosure, and not in an idealized or overly formal sense (unless expressly so defined herein).

As noted above, in a first aspect of the present invention, there is provided a controller, comprising: a first housing piece; a second housing piece; a capacitive touch sensor; a circuit board; and a label, in which:
the first housing piece is ultrasonically welded to the second housing piece,
the capacitive touch sensor is attached to the first housing piece, and
the label in-mold is decorated on the first housing piece.

As also noted above, in a second aspect of the present invention, there is provided a controller, comprising:
a panel having a first housing piece and a second housing piece;
a principal circuit board including at least one display module;
a capacitive touch sensing interface;
a microprocessor mounted on the reverse side of the principal circuit board;
a multi-conductor cable; and
a label,
the first housing piece ultrasonically welded to the second housing piece,
the label in-mold decorated on the first housing piece.

As noted above, in some embodiments, the housing comprises at least a first housing piece and a second housing piece that together define an internal space.

The housing pieces can be made of any of a wide variety of materials. In some embodiments, the housing pieces are made of a material that is suitable for ultrasonic welding (or at least one of the housing pieces comprises at least one region that is made of a material that is suitable for ultrasonic welding). Those of skill in the art are familiar with a variety of materials that are suitable for ultrasonic welding, e.g., polycarbonate, ABS (acrylonitrile butadiene styrene), polyesters, polyalkenes such as polyethylene, and polypheylene oxide. In addition, those of skill in the art can readily test any material to determine whether it can readily be ultrasonically welded with available equipment.

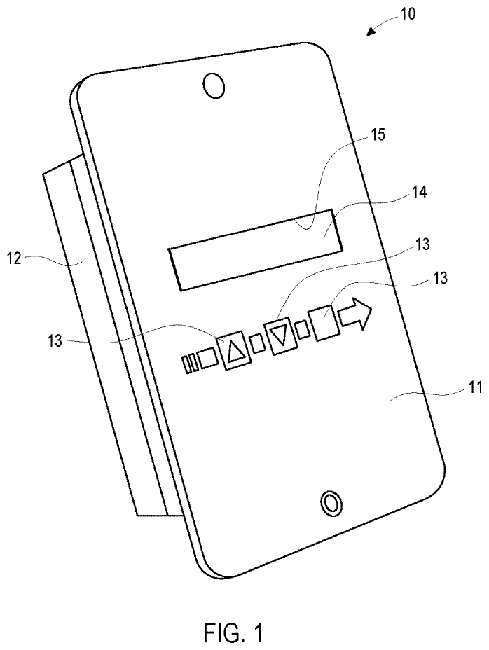

The first housing piece (in some embodiments, the housing piece that faces the user, i.e., the “front housing piece”) has a label embedded within it, in the form of an in-mold decoration comprising graphics. For example, in the embodiment schematically depicted in FIG. 1 (discussed below), the graphics include a series or row of square touch button icons 13, each corresponding to a respective position of a capacitive electrode located on the reverse side of the first housing piece 11.

Those of skill in the art are familiar with in-mold decorating, and any suitable in-mold decorating method can be used in accordance with the present invention.

Those of skill in the art are familiar with a wide variety of displays, and any of such displays can be used as a display in accordance with the present invention. In some embodiments, a device may be embodied as an LCD device, such as, e.g., an E-Ink display of the type used in some E-readers. The display is connected to the circuit board in any suitable way, e.g., with a flex cable. Alternatively, electrodes or connectors of the display (or display module or display modules) are soldered or otherwise connected to conductor traces on a circuit board (e.g., on an upper or back side of a circuit board)

In some embodiments, an array of traces and/or other conductors are provided on the circuit board, to connect input electrodes and output electrodes of a microprocessor to the display, and/or to the array of capacitive electrode pads.

Any suitable components can be mounted on the circuit board. For example, in some embodiments, a microprocessor is mounted on the rear or component side of the board, as are a series of connectors, which permit connection to conductors of a multi-conductor cable. On one side of the circuit board is the capacitive touch sensing interface that has regions that correspond to the graphics in the in-mold decoration on the first housing piece, e.g., icons, discussed earlier. In some embodiments, the capacitive touch sensing interface is adhered to the first housing piece, and is electrically connected via a flex cable to the circuit board. In such embodiments, the presence of the operator's finger at an icon, and at the position on the dielectric material of the first housing piece that is directly opposite a location on the capacitive touch sensing interface, affects the capacitance that is seen by the microprocessor, and this allows the microprocessor to change the mode or setting of the controller, e.g., for an associated pool and spa heater or heat pump.

In some embodiments, a multi-conductor cable provides ingress-protected connections to the circuit board via conductive traces, wires, etc., to electrically connect the controller with apparatus that it controls, such as a pool-and-spa heater or heating and cooling system.

Detailed descriptions of embodiments that correspond to the present invention (and/or aspects of the present invention), and detailed descriptions of features that are provided in some embodiments in accordance with the present invention, are provided hereinafter, in many instances with reference to the accompanying drawings, in which representative embodiments in accordance with the present invention are shown. These detailed descriptions of specific aspects of the present invention, and embodiments in accordance with the present invention, are provided to describe features of the present invention with reference to a specific embodiment or embodiments. The present invention should not be construed as being limited to the specific features in the embodiments set forth herein.

FIG. 1 schematically depicts a controller in the form of a hermetically sealed capacitive touch screen control panel 10 according to a first embodiment. The embodiment depicted in FIG. 1 is designed for a pool and spa application to control a water heater and cooler for controlling temperature of both a backyard or indoor swim pool and a spa or hot tub. Typically, the control panel fits into a receptacle in the housing or cover of the water heater or heat pump equipment, which may also include one or more filters and/or one or more pumps. In this embodiment, a housing comprises a first plastic housing piece 11 and a second plastic housing piece 12 which have been ultrasonically welded together to provide a sealed interior space with complete ingress protection (at least IP67). The first housing piece 11 has a label embedded within it, in the form of an in-mold decoration comprising graphics. In the embodiment depicted in FIG. 1, the graphics include a series or row of square touch button icons 13, each corresponding to a respective position of a capacitive electrode located on the reverse side of the first housing piece 11. In this embodiment, there are three icons 13, namely, one for increase (e.g., raise temperature), one for decrease (e.g., lower temperature), and one for changing a setting. There is also an arrow design signifying swiping across the three icons 13 from left to right to unlock or “wake up” the control, which is discussed below. The icons appear here as squares in this embodiment, but they can be any desired shape in other embodiments. In some embodiments, the first housing piece 11 is be a blank front or plain face, without any clear marking of icons, and illumination from behind the first housing piece indicates the positions of the icons and which one or ones are active for a given mode.

A display 14 is viewable through an opening 15 in the first housing piece 11. In this embodiment, tapping the “set” icon switches the controller 10 among different modes and/or settings. For example, in some embodiments, the increase icon is for increasing the water temperature, the decrease icon is for decreasing the water temperature, the “set” icon toggles between the pool and the spa, and the display digitally shows the set temperature, followed by the current temperature, along with any other desired information, for whichever device the toggle is set to.

As noted above, the controller can have any desired number of touch sensor pads (and corresponding icons), and each can be configured in any desired way, e.g., tapping the “set” icon can move the controller through a sequence of any desired number of modes/functions, and the display can change correspondingly with each tap, i.e., to show which mode/configuration the controller is in, the current set point, and/or the current condition (e.g., temperature, fan speed, etc.).

In some embodiments, the mode select icon is used for scrolling between cooling, heating, desired water temperature, i.e. set point, and actual water temperature. The temperature up and temperature down icons are used for changing the heating and cooling set points for the pool and for the spa. These icons may also have other functions, depending on the application. When none of the icons have been touched for some predetermined time, e.g., 20 seconds, the controller is configured to revert to an off state, i.e., a locked or inactive state, and the user will need to swipe past the four icons to re-activate it.

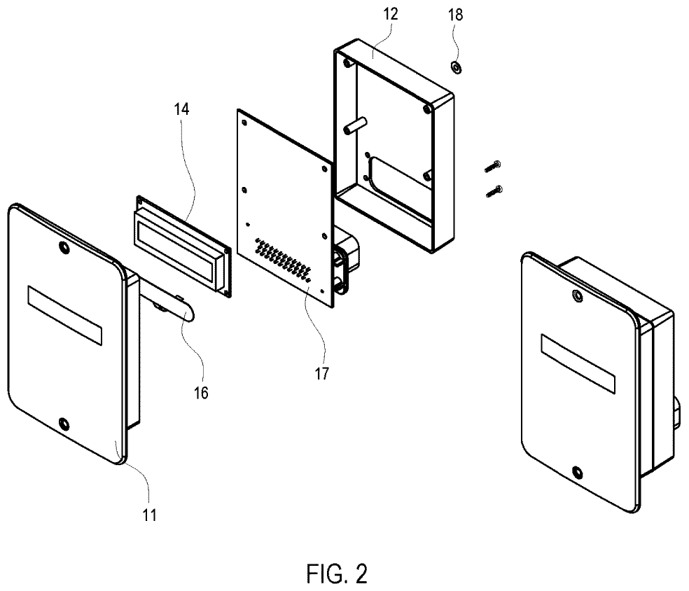

FIG. 2 schematically depicts an exploded view of the controller 10 taken from a first perspective. FIG. 2 shows the first housing piece 11, the second housing piece 12, the display module 14, a capacitive touch sensor 16 (with plural sensor regions), a circuit board 17 and a gore vent 18. The second housing piece 12 is connected by screws to the circuit board 17.

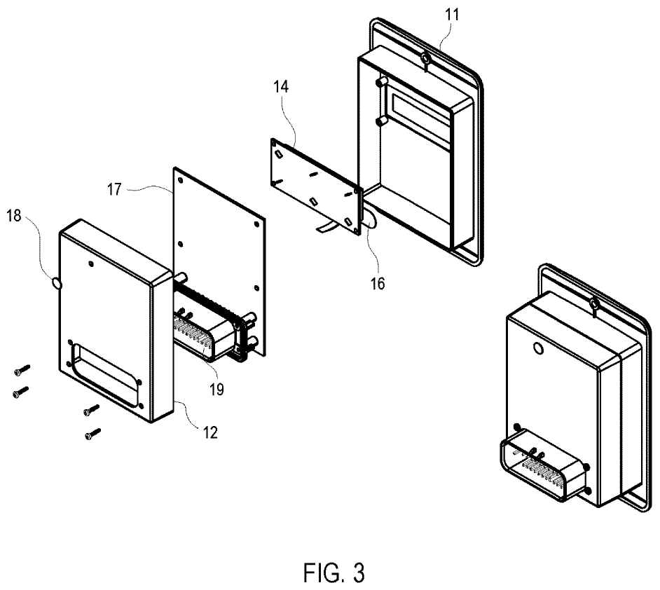

FIG. 3 schematically depicts an exploded view of the controller 10 taken from a second perspective (opposite from the first perspective). As seen in FIG. 3, the controller 10 further comprises pin connectors in the form of an AMPSEAL connector (IP6K9K high seal)

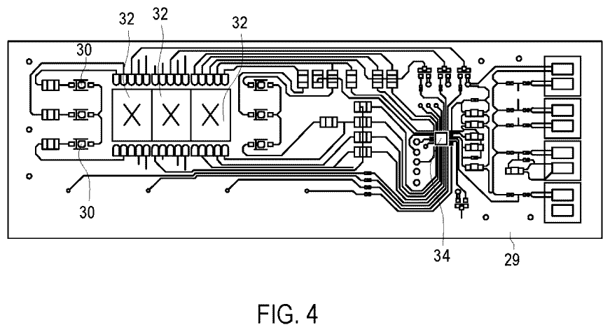

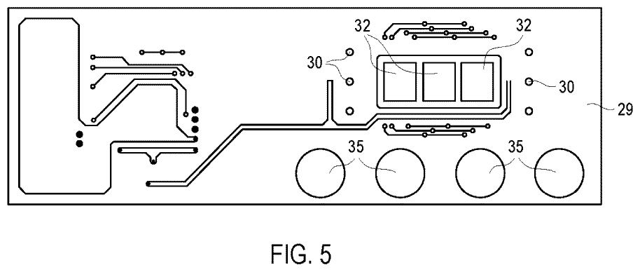

Another example of a suitable printed circuit board 29 is shown in detail in FIGS. 4 and 5. FIG. 4 shows the component or back side of the board 29, and FIG. 5 shows the flat front side. FIG. 4 shows positions of through hole openings 30 where indicator LEDs 31 are to be mounted, three each on either side of an opening 32 in which a display module 33 is to be mounted. This view also shows conductive traces (not numbered) that connect to inputs and outputs of a microprocessor 34, and which also connect with vias that pass through the board to connect with metallized disks 35 or capacitive touch sensors (FIG. 5). Additional traces and grounding pads (not numbered) are printed on the front side of the board.

In this embodiment, the conductive pads 35 are printed on the board 29 and the board is secured adhesively against the first housing piece 11. It is possible, alternatively. to construct a controller of this invention with capacitive touch screen pads printed on the reverse side of the first housing piece or on a thin membrane that is adhered to the first housing piece. In that case compressive connectors, e.g., spring loaded or so-called zebra conductor or elastomeric conductor can connect each of the capacitive touch pads to associated contact pads on the front side of the printed circuit board 29.

If a plain or dead-face presentation is desired, rather than having icons printed or visibly present on the first housing piece 11, the capacitive touch screen pads 35 can be formed with an etched-away design to permit light to pass, the portion of the circuit board directly behind each of the pads 35 can be made of a translucent or transparent material, and an additional LED or equivalent illumination source can be placed behind that area on the component side of the board. This arrangement can provide a back-lit display of the hidden icons by presenting the illuminated design. The associated additional LEDs are turned on when the touch screen is activated. These may all be turned on together, or if desired only those needed for a given operation, such as for raising or lowering temperature set points, may be illuminated, and left off when not active or needed for a given operation. This allows the icons to be illuminated to guide the user. The additional LEDs used for backlighting the icons can be of different colors also, depending on the mode.

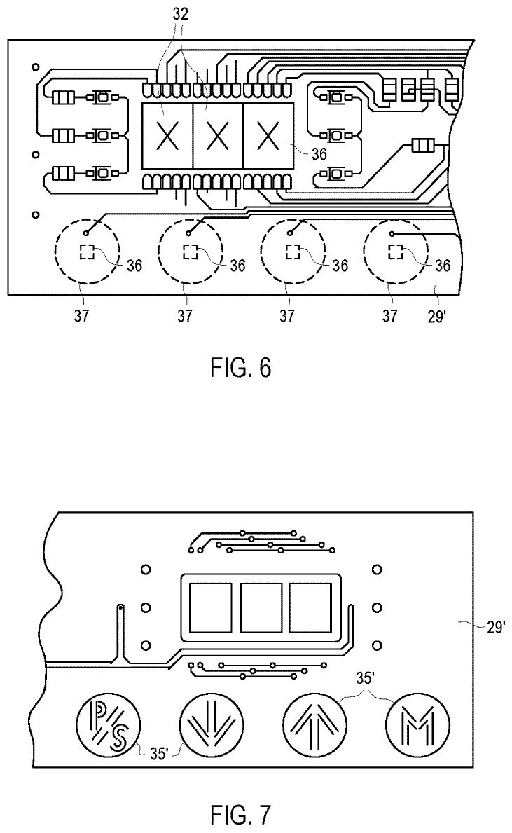

FIGS. 6 and 7 schematically depict partial back and front views of an alternative arrangement of the printed circuit board 29′ for a blank or “dead-face” control panel, where the icons are back-lighted and appear by illuminating auxiliary LEDs 36 as shown in FIG. 6 and located on the board 29′ behind translucent portions 37 that correspond to the positions of the metallized discs 35′, to allow the back-lit illumination through. There are slits or apertures formed in the metallized discs 35′ that form recognizable icons for pool-spa select, temperature down, temperature up, and mode select. The auxiliary LEDs are lit only when needed, and only when the control panel is activated or unlocked, as discussed above.

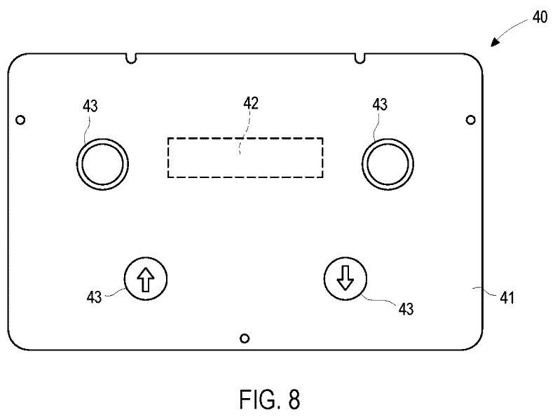

FIG. 8 schematically illustrates an alternative controller 40 configured for a different style cabinet or housing and for different equipment. In this case, the controller 40 is square or rectangular, and has a front plate or panel 41, with a window 42, though which a display module (or display modules) and various indicator LEDs can be seen. In this embodiment, there are four round touch-button icons 43, arranged in a pattern that is not a single row. A printed circuit board, not shown here, would have capacitive metallized pads at positions behind these respective icons 43. This controller can be activated or woken up by touching the icons in some predetermined order, e.g., first the mode icon, then the up-arrow icon, then the down-arrow icon, and then the select icon. Touching the icons 43 in another predetermined order can set the control panel into its rest mode, or this may occur after a period of inactivity, e.g., 20 seconds.

In an outdoor environment, having the controller revert to an inactive or rest mode will prevent inadvertent changing of settings, for example, when a bird or squirrel touches the front panel 41.

Embodiments in accordance with the present invention are described herein in detail in order to provide exact features of representative embodiments that are within the overall scope of the present invention. The present invention is not limited to such detail.

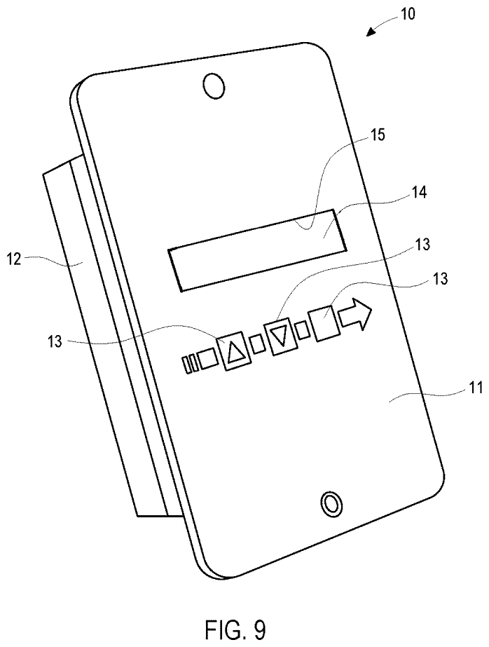

The present invention is also directed to the ornamental design of the front face of the controller depicted in FIG. 9, the ornamental design of the front face of the controller depicted in FIG. 10, and other combinations of the faces of the controller (depicted in FIGS. 11), in which:

FIG. 10 is a front view of the controller;

FIG. 11 is a rear view of the controller;

FIG. 12 is a top view of the controller;

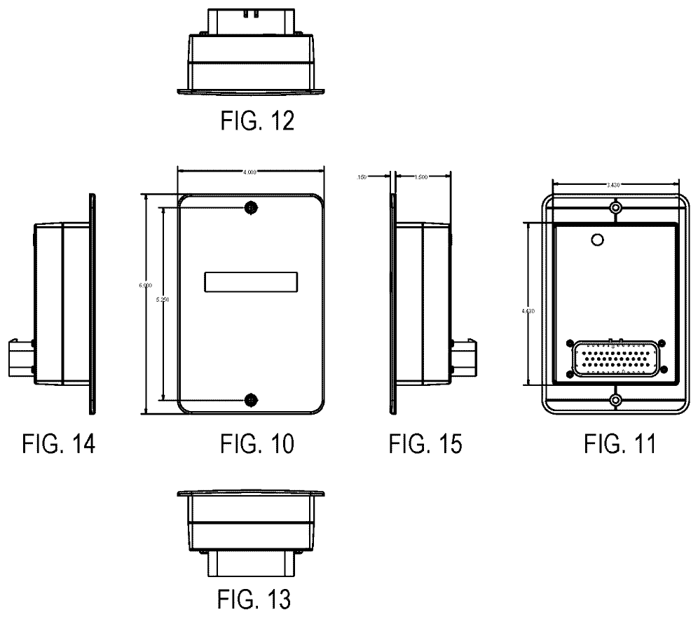

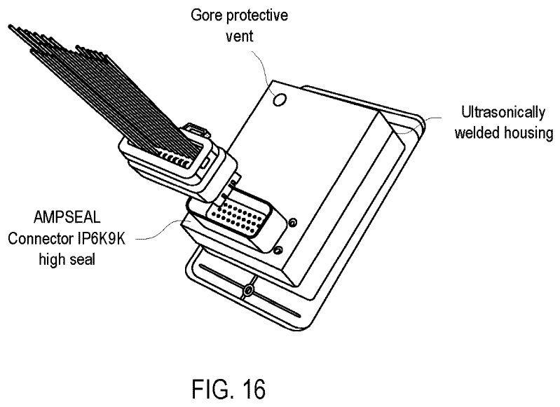

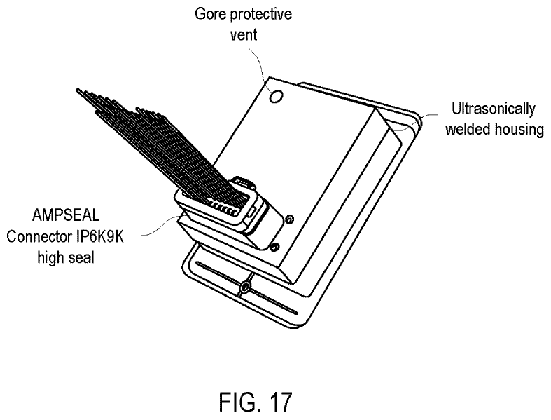

FIG. 13 is a bottom view of the controller;

FIG. 14 is a left side view of the controller; and

FIG. 15 is a right side view of the controller.

Any two or more structural parts of the controllers described herein can be integrated. Any structural part of the controllers described herein can be provided in two or more parts (which are held together, if necessary). Similarly, any two or more functions can be conducted simultaneously, and/or any function can be conducted in a series of steps.

Each component described herein can be a unitary one-piece structure. In some cases, if suitable, two or more structural parts of the devices described herein can be integrated, and/or a component can be provided in two or more parts (which are held together, if necessary). Similarly, any two or more functions can be conducted simultaneously, and/or any function can be conducted in a series of steps.

Furthermore, while certain embodiments of the present invention have been illustrated with reference to specific combinations of elements and attributes, various other combinations may also be provided without departing from the teachings of the present invention. Thus, the present invention should not be construed as being limited to the particular exemplary embodiments described herein and illustrated in the Figures, but may also encompass combinations of elements and attributes of the various illustrated embodiments.

Based on the information provided in the present disclosure, many alterations and modifications may be made by those having ordinary skill in the art, given the benefit of the present disclosure, without departing from the teaching of the present specification, and/or without departing from the spirit and scope of the present invention.

1. A controller, comprising:
a first housing piece;
a second housing piece;
a capacitive touch sensor
a circuit board; and
a label,
the first housing piece ultrasonically welded to the second housing piece,
the capacitive touch sensor attached to the first housing piece,
the label in-mold decorated on the first housing piece.

2. A controller as recited in claim 1, wherein the controller further comprises a display which is visible through an opening in the first housing piece, or through a transparent region in the first housing piece.

3. A controller as recited in claim 1, wherein the controller is configured to control at least one aspect of operation of pool equipment and/or spa equipment by a user touching the capacitive touch sensor.

4. A controller as recited in claim 3, wherein the aspect of operation of pool equipment and/or spa equipment is water temperature.

5. A controller, comprising:
a panel comprising substantially rigid dielectric material having a first housing piece and a second housing piece;
a principal circuit board having a front side and a reverse side, the reverse side being a component side on which circuit elements are mounted, and the front side being flat and without components thereon, the principal circuit board including at least one display module mounted on the reverse side of the principal circuit board, and the at least one display module having a visible display on a front face thereof;
a capacitive touch sensing interface;
a microprocessor mounted on the reverse side of said principal circuit board and having a plurality of input electrodes and output electrodes; an array of conductors on said principal circuit board connecting at least some of the input electrodes and output electrodes of the microprocessor to said at least one display module, and to said capacitive touch sensing interface;
a multi-conductor cable connected with said array of conductors and extending from said principal circuit board and adapted to connect to a control component associated with said interface; and
a label,
the first housing piece ultrasonically welded to the second housing piece,
the label in-mold decorated on the first housing piece.

6. A controller as recited in claim 5, wherein the controller is configured to control at least one aspect of operation of pool equipment and/or spa equipment by a user touching the capacitive touch sensor.

7. A controller as recited in claim 6, wherein the aspect of operation of pool equipment and/or spa equipment is water temperature.

8. A method of making a controller, comprising:
in-mold decorating a label on a first housing piece;
ultrasonically welding the first housing piece to a second housing piece, thereby forming a housing with at least one internal space,
a capacitive touch sensor in the at least one internal space and configured to be activated by touching the first housing piece.

9. A method as recited in claim 8, wherein the controller further comprises a display in the at least one internal space.

10. A method as recited in claim 8, wherein the controller further comprises a circuit board in the at least one internal space.

11. A method as recited in claim 8, wherein the controller is configured to control at least one aspect of operation of pool equipment and/or spa equipment by a user touching the capacitive touch sensor.

12. A method as recited in claim 11, wherein the aspect of operation of pool equipment and/or spa equipment is water temperature.

13-14. (canceled)
